(19) United States
(12) Patent Application Publication
(10) Pub. No.: US 2009/0173385 A1
(43) Pub. Date: Jul. 9, 2009

(54) METHODS TO BOND OR SEAL GLASS PIECES OF PHOTOVOLTAIC CELL MODULES

(76) Inventors: Alan Kost, Tucson, AZ (US); Charles Qian, Gibert, AZ (US); Katherine Liu, Tucson, AZ (US)

Correspondence Address: K&L Gates LLP, 1900 MAIN STREET, SUITE 600, IRVINE, CA, 92614-7319, US

(21) Appl. No.: 12/331,744

(22) Filed: Dec. 10, 2008

Related U.S. Application Data
(60) Provisional application No. 61/012,750, filed on Dec. 10, 2007.

(51) Int. Cl. H01L 31/00; C04B 37/04; B32B 37/02

(52) U.S. Cl. 136/259; 156/325; 156/272.2; 156/280

(57) ABSTRACT

The apparatus and methods of the present disclosure, in a broad aspect, provide novel ways for bonding or sealing pieces of glass of photovoltaic cell modules. These include providing the first piece of glass having a planar surface, providing the second piece of glass having a second planar surface, providing a photovoltaic cell between the first piece of glass and second piece of glass, providing an amount of solder to at least one solder contact area disposed on at least one of the first or second pieces of glass, bringing the first and second pieces of glass into contact at the at least one solder contact area, and heating the solder to about the melting point or working point of the solder to provide the first and second pieces of glass with a bond or seal at the at least one solder contact area.

### CROSS REFERENCE TO RELATED APPLICATIONS

This application claims the benefit of U.S. Provisional Application No. 61/012,750 filed on Dec. 10, 2007, the entirety of which is hereby incorporated by reference.

### FIELD OF THE INVENTION

The present disclosure generally relates to apparatus and associated methods for bonding or sealing pieces of glass useful for producing photovoltaic cell modules.

### BACKGROUND OF THE INVENTION

Throughout history it has been axiomatic that energy, generally defined as the ability to do work, is required for the functioning of a society. Before the advent of modern powered machines, human and animal energies were directly utilized to perform the work necessary to complete menial household tasks to national projects of grand scale. Now, even to meet the basic necessities of life, members of developed and developing nations recognize that adequate supplies of energy are required to power machines and articles of manufacture designed for such purpose. Preparation and cooking of food, heating or cooling a home, and providing clothing among other things, all ultimately require energy. With the advent of modern electrically operated equipment especially, meeting the necessities of life has become easier and enjoying the current luxuries of life possible. Therefore, electricity has emerged as a form of energy in the last century without which a high or even an acceptable standard of living is not possible.

Electricity production generally requires electricity generation which involves converting non-electrical energy to electricity. For electric utilities, it is the first process in the delivery of electricity to consumers. The other processes, electric power transmission and electricity distribution, are normally carried out by the electrical power industry. Electricity is most often generated at a power station by electromechanical generators, primarily driven by heat engines fueled by chemical combustion or nuclear fission.

Production of electricity from carbon-based fuels has a significant drawback. Emissions from electricity generation account for much of the world greenhouse gas emissions, and in the United States, electricity generation accounts for nearly 40% of emissions, the largest of any source. The greenhouse effect, the process by which absorption and emission of infrared radiation by atmospheric gases warm a planet's lower atmosphere and surface is caused by the increased world greenhouse gas emissions.

Human activity since the industrial revolution has increased the concentration of various greenhouse gases, leading to increased radiative forcing from CO₂, methane, tropospheric ozone, chlorofluorocarbons (CFCs) and nitrous oxide. Molecule for molecule, methane is a more effective greenhouse gas than carbon dioxide, but its concentration is much smaller so that its total radiative forcing is only about a fourth of that from carbon dioxide. Some other naturally occurring gases contribute small fractions of the greenhouse effect; one of these, nitrous oxide (N₂O), is increasing in concentration owing to human activity such as agriculture. The atmospheric concentrations of CO₂ and CH₄ have increased by 31% and 149% respectively since the beginning of the industrial revolution in the mid-1700s. These levels are considerably higher than at any time during the last 650,000 years, the period for which reliable data has been extracted from ice cores. From less direct geological evidence it is believed that CO₂ values this high were last attained 20 million years ago. Fossil fuel burning has produced approximately three-quarters of the increase in CO₂ from human activity over the past 20 years.

The present atmospheric concentration of CO₂ is about 385 parts per million (ppm) by volume. Future CO₂ levels are expected to rise due to ongoing burning of fossil fuels and land-use change. The rate of rise will depend on uncertain economic, sociological, technological, and natural developments, but may be ultimately limited by the availability of fossil fuels. However, fossil fuel reserves are sufficient to reach this level and continue emissions past 2100, if coal, tar sands or methane clathrates are extensively used.

Given the harmful effects of global warming and finite sources of available coal and petroleum, other methods of producing electricity have been pursued. One such method is the use of photovoltaics. A photovoltaic cell is a device that converts light energy into electrical energy. A solar cell specifically captures energy from sunlight. Turning solar energy to electrical energy produces zero emissions. Although the use of solar energy had historically been limited to remote places where electrical power lines could not easily reach, government regulations have been imposed to produce at least a certain percentage of electricity from renewable sources of energy. Policies may increasingly make solar energy production less uncommon and perhaps even mainstream.

Solar cells are often electrically connected and encapsulated as a module. Photovoltaic cell modules often have a sheet of glass on the front (sun up) side, allowing light to pass while protecting the semiconductor wafers from the elements (rain, hail, etc.). On the bottom, when there is a thin film photon absorbing material a glass substrate generally is needed. Typically, only thin film solar cells such as CIGS, CdTe, and amorphous silicon have thin film absorbing material. Crystalline silicon silicon cells, currently the most common type, absorb light in thick, bulk pieces of semiconductor. Solar cells are also usually connected in series in modules, creating an additive voltage. Connecting cells in parallel will yield a higher current. Modules are then interconnected, in series or parallel, or both, to create an array with the desired peak DC voltage and current.

The power output of a solar array is measured in watts or kilowatts. In order to calculate the typical energy needs of the application, a measurement in watt-hours, kilowatt-hours or kilowatt-hours per day is often used. A common rule of thumb is that average power is equal to 20% of peak power, so that each peak kilowatt of solar array output power corresponds to energy production of 4.8 kWh per day. To make practical use of the solar-generated energy, the electricity is most often fed into the electricity grid using inverters (grid-connected PV systems); in stand alone systems, batteries are used to store the energy that is not needed immediately.

The top and bottom pieces of glass of various photovoltaic modules (especially those having think film solar cells) generally have to be bonded or sealed so that they stay in place to serve as protective or substrate layers. Such bonding or sealing ideally has maximum longevity and minimal proneness for degradation. Prior glass sealing compositions such as silicone can dry out and lose its ability to maintain a seal or bond after prolonged exposure to sunlight and other elements. As a result, there is a significant need in the art for novel apparatus and associated methods for bonding or sealing pieces of glass useful for photovoltaic cell modules.

### SUMMARY OF THE INVENTION

These and other objects are achieved by the apparatus and methods of the present disclosure which, in a broad aspect, provide novel means for bonding or sealing pieces of glass of photovoltaic cell modules. Surprisingly, suitably engineered and applied solders provide bonds or seals of glass pieces of photovoltaic cell modules which have increased longevity and decreased susceptibility to degradation from the elements such as moisture and prolonged exposure to sunlight as compared to existing methods used to bond or seal pieces of glass of photovoltaic cell modules.

Silicone has been used as a caulk on the outside of the module to prevent moisture from attacking a photovoltaic cell. A thermoplastic such as ethyl vinyl acetate (EVA) can be used to affix the cell to the cover glass. In alternative embodiments of the present disclosure, the instant glass or metal solders can be used one of two ways: it can be used with a thermoplastic such as EVA, in which case its purpose is to prevent moisture and other outside elements from entering the module (sealing); or it can be used without the EVA in which case it performs a dual role—preventing moisture from reaching the cell (sealing) and affixing (bonding) the glass to the cell.

The methods for bonding or sealing pieces of glass of photovoltaic cell modules, in a broad aspect, includes: providing the first piece of glass having a planar surface, providing the second piece of glass having a second planar surface, providing a photovoltaic cell between the first piece of glass and second piece of glass, providing an amount of solder to at least one solder contact area disposed on at least one of the first or second pieces of glass, bringing the first and second pieces of glass into contact at the at least one solder contact area, and heating the solder to about the melting or working point of the solder to provide the first and second pieces of glass with a bond or seal at the at least one solder contact area.

In one embodiment, the solder comprises glass. Alternatively, the glass may comprise PbO, ZnO, B₂O₃, Bi₂O₃, Ag₂O, Al₂O₃, Li₃O, NaO, or SnO; and combinations thereof. In another embodiment, the glass comprises PbO, B₂O₃ and ZnO. In another embodiment, the glass comprises 55% to 65% by weight PbO, 5% to 15% by weight B₂O₃, and 15% to 25% by weight ZnO.

In another embodiment, the solder further comprises at least one thermal expansion coefficient adjusting filler. Alternatively, the filler comprises SiO₂, ZrSiO₄, ZnO, or An₃(PO₄)₂; and combinations thereof.

In another embodiment, the solder is free of lead. In another embodiment, the solder comprises at least one metal. In another embodiment, the solder comprises glass and at least one metal.

In another embodiment, a polymer encapsulating layer is located between the first piece of glass and the photovoltaic cell. Alternatively, the polymer encapsulating layer comprises ethyl vinyl acetate.

In another embodiment, the bottom side (facing away from the sun or other light source) of the first piece of glass is coated with at least one anti-reflective coating.

In another embodiment, before the solder providing step, a bonding or sealing enhancing layer is applied to the first and/or second pieces of glass. Alternatively, the enhancing layer comprises chrome.

In another embodiment, the solder comprises Sn and Bi.

In another embodiment, the heating used to melt the solder is local heating. Alternatively, the heating (whether local or not) may be to a temperature of about 200° C. or more. Alternatively, the heating (whether local or not) may be to a temperature of about 300° C. or more. Alternatively, the heating (whether local or not) may be to a temperature of about 700° C. or less. Alternatively, the heating (whether local or not) may be to a temperature of about 500° C. or less.

In another embodiment, the solder glass has a thermal expansion coefficient that is within about 1 ppm of the thermal expansion coefficient of at least one of the first piece of glass and the second piece of glass. In another embodiment, solder glass has a thermal expansion coefficient that is within about 0.5 ppm of the thermal expansion coefficient of at least one of the first piece of glass and the second piece of glass.

In another embodiment, the solder glass has a melting temperature of about 700° C. or less. Alternatively, solder glass has a melting temperature of about 500° C. or less.

In another embodiment, the first piece of glass and the second piece of glass are rendered irregular at or near the at least one solder contact area prior to the heating step. In another embodiment, the solder glass is provided in a medium selected from a solvent, a binder, or combinations thereof.

In another embodiment, the first piece of glass and the second piece of glass respectively comprise a first and second edge and the at least one solder contact area is disposed at or near at least one of the first or second edges.

In another embodiment, the heating step comprises applying heat only at or near the at least one solder contact area. In another embodiment, the heating step comprises applying heat to at least one of the first or second planar surfaces of the first piece of glass and the second piece of glass only at or near the solder glass contact point.

In another embodiment, the first piece of glass and the second piece of glass are bonded with a distance of about 0.1, about 0.5, or about 1 μm to about 5, about 4, or about 3 μm between the planar surfaces. In another embodiment, the first piece of glass and the second piece of glass are bonded with a distance of about 100 μm, or about 200 μm, or about 300 μm to about 600 μm, or about 500 μm, or about 400 μm between the planar surfaces.

In another embodiment, when a polymer encapsulating layer is located between the first piece of glass and the second piece of glass, the heating step comprises applying heat to at least about the melting point or working point of the polymer encapsulating layer and up to about the melting point or working point of the solder glass. In another embodiment, the heating comprises directed light heating or infrared heating.

The present disclosure also relates to photovoltaic cell modules with sealed or bonded first and second pieces of glass. In one embodiment, a photovoltaic cell module comprises a first piece of glass; a second piece of glass; a photovoltaic cell located between said first and second pieces of glass; wherein said first piece of glass and the second piece of glass are in contact at one or more solder contact areas; and further wherein said first and second pieces of glass are bonded or sealed with a solder at the one or more solder contact areas.

In another embodiment of the present photovoltaic cell modules, the solder comprises glass. In another embodiment of the present photovoltaic cell modules, the glass comprises PbO, ZnO, B₂O₃, Bi₂O₃, Ag₂O, Al₂O₃, Li₃O, NaO, or SnO; and combinations thereof. In another embodiment of the present photovoltaic cell modules, the glass comprises PbO, B₂O₃ and ZnO. In another embodiment of the present photovoltaic cell modules, the glass comprises 55% to 65% by weight PbO, 5% to 15% by weight B₂O₃, and 15% to 25% by weight ZnO.

In another embodiment of the present photovoltaic cell modules, the solder further comprises at least one thermal expansion coefficient adjusting filler. In another embodiment of the present photovoltaic cell modules, the filler comprises SiO₂, ZrSiO₄, ZnO, or An₃(PO₄)₂; and combinations thereof. In another embodiment of the present photovoltaic cell modules, the solder is free of lead. In another embodiment of the present photovoltaic cell modules, the solder comprises at least one metal. In another embodiment of the present photovoltaic cell modules, the solder comprises glass and at least one metal.

In another embodiment of the present photovoltaic cell modules, a polymer encapsulating layer is located between the first piece of glass and the photovoltaic cell.

In another embodiment of the present photovoltaic cell modules, the polymer encapsulating layer comprises ethyl vinyl acetate. In another embodiment of the present photovoltaic cell modules, the bottom side of the first piece of glass is coated with at least one anti-reflective coating.

In another embodiment of the present photovoltaic cell modules, a bonding or sealing enhancing layer is applied to the first and/or second piece of glass. In another embodiment of the present photovoltaic cell modules, the enhancing layer comprises chrome.

In another embodiment of the present photovoltaic cell modules, the solder comprises Sn and Bi. In another embodiment of the present photovoltaic cell modules, the solder glass has a thermal expansion coefficient that is within about 0.5 ppm of the thermal expansion coefficient of at least one of the first piece of glass and the second piece of glass. In another embodiment of the present photovoltaic cell modules, the solder glass has a thermal expansion coefficient that is within about 0.5 ppm of the thermal expansion coefficient of at least one of said first piece of glass and said second piece of glass. In another embodiment of the present photovoltaic cell modules, the solder glass has a melting temperature of about 700° C. or less. In another embodiment of the present photovoltaic cell modules, the solder glass has a melting temperature of about 500° C. or less. In another embodiment of the present photovoltaic cell modules, the first piece of glass and the second piece of glass are rendered irregular at or near the one or more solder contact areas prior to heating. In another embodiment of the present photovoltaic cell modules, the first piece of glass and the second piece of glass respectively comprise a first and second edge and the at least one solder contact area is disposed at or near at least one of the first or second edges.

### BRIEF DESCRIPTION OF THE DRAWINGS

FIG. 1 illustrates a photovoltaic cell module with the top and bottom pieces of glass sealed with a presently disclosed solder.

FIG. 2 illustrates a sealed photovoltaic cell module with the top and bottom pieces of glass sealed with a presently disclosed glass solder, showing local heat application points.

### DETAILED DESCRIPTION OF THE INVENTION

A photovoltaic cell (e.g., solar cell) converts light energy to electrical energy by photogenerating charge carriers (e.g., electrons and holes) in at least one photon-absorbing material such as a semiconductor (e.g., silicon, CIGS, CdTe, CIS, organic polymer, or combinations thereof). Charge carriers (e.g., electrons) move toward electrically-conductive contacts where electrical energy may then be further transported and/or utilized. This photovoltaic effect often occurs within a “module.” A photovoltaic module typically contains at least one photon-absorbing semiconductor material, elements to protect or serve as a substrate to the at least one photon-absorbing material, and electrical contacts/wiring.

Described herein are methods to join, bond or seal two pieces of glass. Typically these two pieces are the top protective glass layer which protects the photovoltaic cell from the elements (rain, hail, etc.) and a glass substrate layer onto which photon absorbing materials such as thin film photon absorbing materials may be placed. Because previous bonding compositions have the disadvantage of degrading or otherwise being rendered unsuitable to maintain a glass bond over time, particularly if the composition was exposed to the elements, the present novel advantages methods for bonding or sealing glass are provided.

One embodiment of the present methods for bonding or sealing a includes: providing a first piece of glass having a planar surface, providing a second piece of glass having a second planar surface, providing a photovoltaic cell between the first piece of glass and second piece of glass, providing an amount of solder to at least one solder contact area disposed on at least one of the first or second pieces of glass, bringing the first and second pieces of glass into contact at the at least one solder contact area, and heating the solder to about the melting or working point of the solder to provide the first and second pieces of glass with a bond or seal at the at least one solder contact area.

Solar cells are often electrically connected and encapsulated as a module. Photovoltaic cell modules often have a sheet of glass on the front (sun up) side, allowing light to pass while protecting the semiconductor wafers from the elements (rain, hail, etc.). The first piece of glass as herein used is glass typically used as a top protective layer of a photovoltaic cell module. This piece of glass can be considered then as the layer that most directly faces a light source such as the sun. The second piece of glass as herein used refers to glass which is typically used as the glass substrate upon which generally a thin film photon absorbing material is placed. Thin film photon absorbing layers, unlike bulk silicon, are deposited on a substrate that provides structural integrity.

A photovoltaic cell is provided between the first piece of glass and the second piece of glass. A photovoltaic cell includes at least one semiconductor material which may be used for photoabsorption of photons. In addition to silicon, a semiconductor material which may be used for photo-absorption of photons in accordance with the present disclosure is copper indium gallium diselenide (CIGS). CIGS can be configured in at least one layer, preferably in thin-film composites. Thin-film technologies reduce the amount of light absorbing semiconductor material required to make a photo-voltaic cell. This can lead to reduced costs when compared to solar cells made from bulk materials.

Higher efficiencies may be obtained by using optics to concentrate the incident light. The use of gallium increases the optical bandgap of the CIGS layer as compared to CIS (another photo-absorbing semiconductor material which may be utilized according to the present disclosure). Selenium allows for better uniformity across the layer of CIGS and so the number of recombination sites in the film are reduced which benefits the quantum efficiency and thus the conversion efficiency. CIGS films may be manufactured by various methods. These include vacuum-based processes which co-evaporate or co-sputter copper, gallium, and indium, and then anneal the resulting film with a selenide vapor to form a final CIGS structure. Non-vacuum based alternative processes deposit nanoparticles of the precursor materials on a substrate and sinter them in situ. Also, CIGS can be printed directly onto molybdenum coated glass sheets.

Cadminum telluride (CdTe) is another photon-absorbing semiconductor material which may be utilized within the scope and teachings of the present disclosure. CdTe is an efficient light-absorbing material which can be used primarily in thin-film photovoltaic cells. CdTe is relatively easy to deposit and therefore is considered suitable for large-scale production.

CIS is an abbreviation for general chalcopyrite films of copper indium selenide. An example is CuInSe₂ which is of interest for photovoltaic applications including elements from groups I, III and VI in the periodic table. CIS has high optical absorption coefficients and versatile optical and electrical characteristics which may be manipulated and tuned. CIS is a photon-absorbing semiconductor which may be utilized within the scope and teachings of the present disclosure. CIS most often is used to make a thin-film of photon absorbing material for a solar cell.

Organic polymers may also be used as a photon-absorbing semiconductor material. These materials may be made, for example, from polymers and small molecule compounds such as polyphenylene vinylene, copper phthalocyanine (a blue or green organic pigment) and carbon fullerenes. Organic polymers may be especially important for photovoltaic cells in which mechanical flexibility and disposability are important.

It is within the scope and teachings of the present disclosure that the above-mentioned photon-absorbing semiconductor materials may be used alone or in combination. Also, the materials may be in more than one layer, each layer having a different type of photon-absorbing semiconductor material or having combinations of the photon-absorbing semiconductor materials in separate layers. One of ordinary skill in the art would be able to optimally configure the amount and construction of the materials to maximize the quantum and overall efficiencies of a photovoltaic cell in accordance with the present disclosure.

Optionally, at least one cover layer is located above the at least one photon-absorbing semiconductor material for photovoltaic cell according to the present disclosure. The cover layer(s) may serve various purposes. This layer can serve as an n-type or p-type semiconductor. Generally, a commonly known solar cell is configured as a large-area p-n junction. A p-n junction is a junction formed by combining p-type and n-type semiconductors together in close contact. The term junction refers to the region where the two regions of the semiconductors meet. It can be thought of as the border region between the p-type and n-type blocks. Free carriers created by light energy are separated by the junction and contribute to current.

When the material is silicon, n-type dopant is diffused into one side of a p-type wafer or vice versa. If a piece of p-type silicon is placed in intimate contact with a piece of n-type silicon, then a diffusion of electrons occurs from a region of high electron concentration (the n-type side of the junction) into a region of low electron concentration (p-type side of the junction). When electrons diffuse across a p-n junction, they recombine with holes on the p-type side. The diffusion of carriers does not happen indefinitely however, because of an electric field which is created by the imbalance of charge immediately either side of the junction which this diffusion creates. The electric field established across the p-n junction creates a diode that promotes current flow in only one direction across the junction. Electrons may pass from the n-type side into the p-type side, and holes may pass from the p-type side to the n-type side. This region where electrons have diffused across the junction is called the depletion region because it no longer contains any mobile charge carriers.

An example of an n-type semiconductor which can form the n-type side of a p-n junction within the scope and teachings of the present disclosure is cadmium sulfide (CdS). It is yellow in color and is a semiconductor. Cadmium sulfide can be produced from volatile cadmium alkyls. An example is the reaction of dimethylcadmium with diethyl sulfide to produce a film of CdS using MOCVD techniques. It is important to point out that CdS may absorb those photons having a wavelength which may otherwise be usable or capable of absorption by a photon-absorbing semiconductor material such as CIGS. One of ordinary skill in the art will recognize that this may be partly why CdS generally has been deposited as a very thin film. However, CdS is often a necessary part of a photovoltaic cell and absorption of otherwise usable photons by CdS, especially in the blue range of the solar radiation which reaches the earth, reduces the quantum efficiency of a photon-absorbing semiconductor material and, therefore, the overall efficiency of a solar cell.

Alternatively, the cover layer may have at least one additional conductive layer. For example, these may be ZnO and/or ITO (indium tin oxide), or a combination thereof. These conductors of electrical charge may be, for example, in the form of thin films. These additional conductive layers may be engineered to be as transparent as possible to allow light to pass through it so that it may reach the photon-absorbing semiconductor layer underneath. However, one of ordinary skill in the art will recognize that the at least one additional conductive layer may also, like the CdS layer, absorb photons which would otherwise be useful if absorbed by the photon-absorbing semiconductor material underneath. The additional conductive layer(s) can serve as ohmic contacts to transport photogenerated charge carriers away from the light absorbing material.

It is also within the scope and teaching of the present disclosure alternatively to include metal contacts which are located nearer to the top (closer to the sun) of a photovoltaic cell. Because these metal contacts are located nearer to the top, it would be preferable that they have the least surface area as possible to allow passage of external photons to the at least one photon-absorbing semiconductor materials located underneath.

As described herein, presently disclosed photovoltaic cells alternatively also includes at least two electrically-conductive materials located above and below the at least one photon-absorbing semiconductor material. An example of this material within the scope and teachings of the present disclosure is molybdenum. Further alternatively, molybdenum is the conductive material below the at least one photon-absorbing material and a metal electrode is the electrically-conductive material above the at least one photon-absorbing material. Generally, the ability of molybdenum to withstand extreme temperatures without significantly expanding or softening makes it useful in applications that involve intense heat, including the manufacture of aircraft parts, electrical contacts, industrial motors, and filaments.

As used herein when the first and second pieces of glass of a photovoltaic cell module are “bonded” with the presently disclosed solders, the strength of the two glasses being held together is primarily due to the action or qualities of the provided solders. When the first and second pieces of glass of a photovoltaic cell module are “sealed” the strength of the two glasses being held together is not primarily due to the action or qualities of the provided solders. When a polymer encapsulating layer such as ethyl vinyl acetate is provided, this polymer encapsulating layer adheres to a thin film photon absorbing material such as CIGS which has been adhered to a glass substrate, or it could be to another layer of a photovoltaic cell. The polymer encapsulating layer also adheres to the top protect glass (or the first piece of glass). Heating and setting of the polymer encapsulating layer bonds the polymer encapsulating layer to the top glass and to the photon absorbing layer. This thus provides bonding between the top glass and bottom glass.

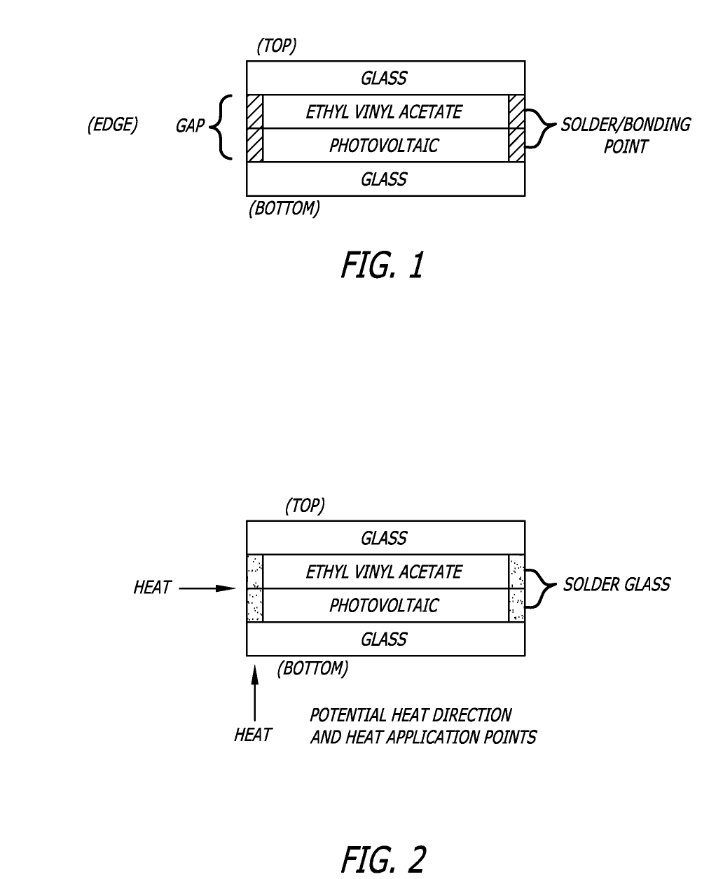

This is illustrated by FIGS. 1 and 2. In FIG. 1, the top glass (sun facing) is bonded to ethyl vinyl acetate which is bonded to the photovoltaic cell or photon absorbing layer of such a cell. This layer is bonded to the underlying glass substrate. Therefore, heating the polymer encapsulating layer such as ethyl vinyl acetate, and cooling it provides an enclosure of a photovoltaic cell where the two ends are two pieces of glass (top protective and substrate).

Ethylene vinyl acetate or ethyl vinyl acetate (also known as EVA) is the copolymer of ethylene and vinyl acetate. The weight percent vinyl acetate usually varies from 10 to 40% with the remainder being ethylene. It is a polymer that approaches elastomeric materials in softness and flexibility, yet can be processed like other thermoplastics. The material has good clarity and gloss, barrier properties, low-temperature toughness, stress-crack resistance, hot-melt adhesive water proof properties and resistance to UV radiation. EVA has little or no odor and is competitive with rubber and vinyl products in many electrical applications.

EVA foam is used as padding in equipment for various sports such as ski boots, hockey, boxing, mixed martial arts, wakeboard boots, and waterski boots. EVA is also used in biomedical engineering applications as a drug delivery device. The EVA is dissolved in an organic solvent (e.g., methylene chloride). Powdered drug and filler (typically an inert sugar) are added to the liquid solution and rapidly mixed to obtain a homogeneous mixture. The drug-filler-polymer mixture is then cast into a mold at −80 degrees and freeze dried until solid. These devices are used in drug delivery research to slowly release a compound over time. While the polymer is not biodegradable within the body, it is quite inert and causes little or no reaction following implantation.

Hot glue sticks are usually made from EVA, usually with additives like wax and resin. EVA is also used as a clinginess-enhancing additive in plastic wraps. EVA is typically used as a shock absorber in sports shoes, for example. EVA can be recognized in many Crocs brand shoes and accessories, in the form of a foam. It is also used in the photovoltaics industry as an encapsulation material for silicon cells in the manufacture of photovoltaic modules.

Solder is provided to solder contact area(s) disposed on at least one of the first or second pieces of glass. Solder as used herein, in order to simplify or otherwise improve application maybe provided in several forms including tape, in a solvent (e.g. water), or in a binder (e.g., paste or gel). Heating creates the bonds or seals in accordance with the present disclosure. The heating temperature may be important for glass bonding applications used to create enclosures, and as used herein for a photovoltaic cell module, for temperature sensitive components, e.g. photovoltaic cells and electrical components. When the first and second pieces of glass are brought together they should contact at least at one or more of the solder contact areas. The heating bring the solder about to its melting point or working point. Working point as herein used refers to the temperature required for the present solders to reach for them to be able to properly bond or seal the pieces of glass of a photovoltaic cell module. Metal solder is usually heated to about its melting point. For glass solder, a softening temperature is usually specified but sealing may be carried out at a higher working temperature. Cooling provides the first and second pieces of glass with a bond or seal at the at least one solder contact area.

In one embodiment, the solder comprises glass. The glass in the solder may comprise PbO, ZnO, B₂O₃, Bi₂O₃, Ag₂O, Al₂O₃, Li₃O, NaO, or SnO; and combinations thereof. In a preferred embodiment, the glass in the solder comprises PbO, B₂O₃ and ZnO. Alternatively, the glass in the solder comprises 55% to 65% by weight PbO, 5% to 15% by weight B₂O₃, and 15% to 25% by weight ZnO. A typical composition of solder glass within the scope and teachings of the present disclosure is 62% PbO, 12% B₂O₃, and 21% ZnO which has a softening temperature of 380° C. (Vacuum Sealing Techniques,” A. Roth, (AIP Press, Woodbury, N.Y., 1994), Table 3.6). Such a glass mixture can be made by grinding the oxides into powders and mixing the powders. Water may be added to make a paste of the powder and this can be painted onto a bottom piece of glass. The glass then can be heated to remove water from the paste leaving a solder glass film on the glass. A top sheet of glass can be placed on top of the bottom sheet to form the solder glass combination. The solder may be heated with a laser or with a lamp in alternative embodiments to melt and form a bond between the two glass sheets.

To produce solders with a desired thermal expansion coefficient, “fillers” can be added such as SiO₂, ZrSiO₄, ZnO, or An₃(PO₄)₂; and combinations thereof. Generally, when the temperature of a substance changes, energy that is stored within the intermolecular bonds between atoms changes. When stored energy increases, so does the length of the molecular bonds. As a result, solids typically expand in response to heating and contract on cooling; this dimensional response to temperature change is expressed by its coefficient of thermal expansion. Different coefficients of thermal expansion can be defined for a substance depending on whether the expansion is measured by: linear thermal expansion, area thermal expansion, or volumetric thermal expansion. These characteristics are closely related. A volumetric thermal expansion coefficient can be defined for both liquids and solids. A linear thermal expansion can only be defined for solids, and is common in engineering applications. Some substances expand when cooled, such as freezing water, so they have negative thermal expansion coefficients.

Preferably, when glass solder is used, selecting solder and pieces of glass that have relatively close coefficients of thermal expansion results in more resilient bonds. Thus, in one embodiment the first piece of glass and the second piece of glass are bonded with a distance of about 5, about 4, or about 3 μm between the planar surfaces. Alternatively, first piece of glass and the second piece of glass are bonded with a distance of about 100 μm, or about 200 μm, or about 300 μm to about 600 μm, or about 500 μm, or about 400 μm between the planar surfaces.

In a preferred embodiment, the herein provided solders are free of lead. Lead is a poisonous metal that can damage nervous connections (especially in young children) and cause blood and brain disorders. Because of its low reactivity and solubility, lead poisoning usually only occurs in cases when the lead is dispersed, like when sanding lead based paint, or long term exposure in the case of pewter tableware. Long term exposure to lead or its salts (especially soluble salts or the strong oxidant PbO₂) can cause nephropathy, and colic-like abdominal pains.

In another embodiment, the provided solder comprises at least one metal. The solder may also comprise both glass and at least one metal. Four elements are preferred for metal solders as presently provided to seal or bond pieces of glass of photovoltaic cell modules. These are Sn, Bi, In and Zn. The melting points of these elements respectively are 232° C., 271° C., 156.7° C. and 419° C. Because In is currently expensive, Sn, Bi and Zn are the more preferred for metal solder. These may be in the form of metal alloys as well. For example, 58% by weight Bi and 42% by weight Sn allow has a melting temperature of 137° C. This melting temperature is relatively low and therefore lessen the risk of damaging the photon absorbing material of the photovoltaic cell such as CIGS.

Another solder within the scope and teachings of the present disclosure which may be used to seal or bond pieces of glass of a photovoltaic cell module is a binary Sn—Al lead free solder alloy having a melting point of about 231° C. It is called SONIC SOLDER® made by EWI®. This solder contains Sn an Al which are two fairly abundant and inexpensive materials currently. Second this solder can be used with ultrasonic soldering—a procedure that allows the solder to bind to glass without the use of a primer layer such as chromium.

In another embodiment, on the bottom side of the first piece of glass may be coated with at least one anti-reflective coating. Especially, when no polymer encapsulating layer is present and solder contact area(s) are the edges that a first piece of glass and a second pieces of glass respective may comprise, there may be reflection because of a gap that might be present. This gap typically would contain air and because of the different refractive indices, reflection problems may occur. Application of one or more anti-reflective coatings may alleviate this problem.

Anti-reflective or antireflection (AR) coatings are a type of optical coating applied to the surface of lenses and other optical devices to reduce reflection. In some applications such as those concerning the present disclosure, the primary benefit is the elimination of the reflection itself, such as a coating on eyeglass lenses that makes the eyes of the wearer more visible, or a coating to reduce the glint from a covert viewer's binoculars or telescopic sight.

Many coatings consist of transparent thin film structures with alternating layers of contrasting refractive index. Layer thicknesses are chosen to produce destructive interference in the beams reflected from the interfaces, and constructive interference in the corresponding transmitted beams. This makes the structure's performance change with wavelength and incident angle, so that color effects often appear at oblique angles. A wavelength range must be specified when designing or ordering such coatings, but good performance can often be achieved for a relatively wide range of frequencies: usually a choice of IR, visible, or UV is offered.

Further, in another embodiment, before the soldering step, a bonding or sealing enhancing layer may be applied to the first and/or second pieces of glass. One example of such an enhancing layer in accordance with the scope and teachings of the present disclosure is chromium. Application of chrome may enhance the bonding of solder to the pieces of glass by bonding of solder to chrome. Chromium tenaciously bonds to glass and therefore may enhance the action of the presently provided solders.

In some embodiments, the provided solders are melted with heat. This heating may be local heating, especially when glass solder is used because higher temperatures may be required to melt glass solder compared to metal solders. If the temperature required can damage any of the components of a photovoltaic cell such as the CIGS layer, local heating to only the solder points may avoid damage. The heating may be to a temperature of about 200° C. or more, 300° C. or more, 700° C. or less, or 500° C. or less. When the provided solder comprises glass, alternatively the solder glass itself has a meting temperature of about 700° C. or less and 500° C. or less. The heat may be provided to all bonding or sealing points separately or simultaneously. The heat may be applied simultaneously to all bonding points to avoid heating and reheating, and the accompanying stress in some embodiments. In addition, glass pieces to be bonded or sealed may be preheated to a temperature at or below melting point or working point of the lowest melting point or working point constituent (e.g., the glass solder) such that the heating is conducted in stages, e.g. preheating and heating to melt solder glass. For example, the glass sheets may be pre-heated to 150° C., the solder glass applied to the intended bonding point(s), e.g the entire outer periphery of the sheet(s), and heating resumed to about 400° C., the melting point or working point of the solder glass. If the glass sheets were to enclose a photovoltaic cell, e.g. to create a photovoltaic module, the entire photovoltaic module may be preheated or heated together and the glass bonded to enclose the photovoltaic cell.

In some embodiments, it may be desirable to make the surface of the glass irregular at or near the intended bonding point. For example, the surfaces may be made irregular by roughing the surface, etching the surface, providing channels or grooves in the surface, and other irregularities known to the skilled artisan. These surface irregularities may improve bonding between the solder glass and the glass surface. In addition, surface irregularities may provide flexibility in glass bonding geometry, e.g. the distance separating two planar glass surfaces. Methods to produce surface irregularities include mechanical means, chemical means and other means known to skilled artisans. It will be apparent that the surface irregularity should be provided at a time before the heating/bonding/sealing step.

In some embodiments, the pieces of glass may be provided in the form of sheets having peripheral edges. In some embodiments, the bonding point with a planar surface at or near the peripheral edge of one piece of glass with the planar surface at or near the peripheral edge of the other piece of glass. In other embodiments, other items may be sandwiched between the sheet of glass. In other embodiments, the sandwiched items are not disposed at the peripheral edges of the sheets of glass, e.g. are smaller than and centered within the peripheral edges of the two sheets of glass. In that regard, applying heat only at or near the solder glass contact point at the peripheral edges of the glass sheets will be less likely to damage the sandwiched item(s). One example of a sandwiched item may be a polymer layer, e.g. a polymer encapsulating layer such as ethyl vinyl acetate, which is commonly used in photovoltaics. Another example of a sandwiched item may be a photon-absorbing material, e.g. a semiconductor. The peripheral edges in a preferred embodiment are about 1 to 2 cm in width. The edges are illustrated by FIGS. 1 and 2.

In the case of sandwiched items and for other reasons, it may be desirable to provide a gap between two bonded pieces of glass. For example, two pieces of glass may be bonded with a minimum gap of several microns in order to accommodate, for example, the layers in a thin film photovoltaic cell. In embodiments where other (e.g. those where a photovoltaic and ethyl vinyl acetate layer) items are sandwiched, the pieces of glass may be bonded with a minimum gap of about 100 μm, or about 200 μm, or about 300 μm. The maximum gap may be about 600 μm, or about 500 μm, or about 400 μm. In other embodiments, a polymer layer, e.g. ethyl vinyl acetate, may be disposed between said first and second pieces of glass and heating step includes applying heat to at least about the melting point or working point of the polymer and up to about the melting point or working point of the solder glass.

The heating may be carried out, for example, using directed light heating. Directed light heating includes, for example, heat applied to the planar surface on the piece of glass that is opposite the planar surface that will be bonded. The directed light heat may be designed such that it passes through the pieces of glass and primarily heats the solder glass. The heating may also include heating by applying a heating coil at or near the intended bonding site. The coil is heated by resistive heating, but it is the infrared light from the coil that heats the solder. I would call this IR heating, and it is a special case of heating with light. If you decide to change this terminology, be sure to change it elsewhere in the application.] Regardless of the heating mechanism, the heat may be applied directly to and through the planar surface (e.g., heat directed to cross the planar surface). In any event, it may be desirable to apply heat only at or near the intended bonding site to conserve energy and avoid damaging any items disposed between the sheets of glass. As discussed, the heat may be applied at the edges of the glass pieces, at the plane of at least one of the glass pieces or both.

The present disclosure also relates to photovoltaic cell modules with sealed or bonded first and second pieces of glass. In one embodiment, a photovoltaic cell module comprises a first piece of glass; a second piece of glass; a photovoltaic cell located between said first and second pieces of glass; wherein said first piece of glass and said second piece of glass are in contact at one or more solder contact areas; and further wherein said first and second pieces of glass are bonded or sealed with a solder at said one or more solder contact areas.

In another embodiment of the present photovoltaic cell modules, the solder comprises glass. In another embodiment of the present photovoltaic cell modules, the glass comprises PbO, ZnO, B₂O₃, Bi₂O₃, Ag₂O, Al₂O₃, Li₃O, NaO, or SnO; and combinations thereof. In another embodiment of the present photovoltaic cell modules, the glass comprises PbO, B₂O₃ and ZnO. In another embodiment of the present photovoltaic cell modules, the glass comprises 55% to 65% by weight PbO, 5% to 15% by weight B₂O₃, and 15% to 25% by weight ZnO.

In another embodiment of the present photovoltaic cell modules, the solder further comprises at least one thermal expansion coefficient adjusting filler. In another embodiment of the present photovoltaic cell modules, the filler comprises SiO₂, ZrSiO₄, ZnO, or An₃(PO₄)₂; and combinations thereof. In another embodiment of the present photovoltaic cell modules, the solder is free of lead. In another embodiment of the present photovoltaic cell modules, the solder comprises at least one metal. In another embodiment of the present photovoltaic cell modules, the solder comprises glass and at least one metal

In another embodiment of the present photovoltaic cell modules, a polymer encapsulating layer is located between the first piece of glass and the photovoltaic cell. In another embodiment of the present photovoltaic cell modules, the polymer encapsulating layer comprises ethyl vinyl acetate. In another embodiment of the present photovoltaic cell modules, the bottom side of the first piece of glass is coated with at least one anti-reflective coating.

In another embodiment of the present photovoltaic cell modules, a bonding or sealing enhancing layer is applied to the first and/or second piece of glass. In another embodiment of the present photovoltaic cell modules, the enhancing layer comprises chromium.

In another embodiment of the present photovoltaic cell modules, the solder comprises Sn and Bi. In another embodiment of the present photovoltaic cell modules, the solder glass has a thermal expansion coefficient that is within about 0.5 ppm of the thermal expansion coefficient of at least one of the first piece of glass and the second piece of glass. In another embodiment of the present photovoltaic cell modules, the solder glass has a thermal expansion coefficient that is within about 0.5 ppm of the thermal expansion coefficient of at least one of said first piece of glass and said second piece of glass. In another embodiment of the present photovoltaic cell modules, the solder glass has a melting temperature of about 700° C. or less. In another embodiment of the present photovoltaic cell modules, the solder glass has a melting temperature of about 500° C. or less. In another embodiment of the present photovoltaic cell modules, the first piece of glass and the second piece of glass are rendered irregular at or near the at least one solder contact area prior to heating. In another embodiment of the present photovoltaic cell modules, the first piece of glass and the second piece of glass respectively comprise a first and second edge and the at least one solder contact area is disposed at or near at least one of the first or second edges.

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments of this invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Specific embodiments disclosed herein may be further limited in the claims using consisting of or and consisting essentially of language. When used in the claims, whether as filed or added per amendment, the transition term “consisting of” excludes any element, step, or ingredient not specified in the claims. The transition term “consisting essentially of” limits the scope of a claim to the specified materials or steps and those that do not materially affect the basic and novel characteristic(s). Embodiments of the invention so claimed are inherently or expressly described and enabled herein.

Furthermore, numerous references have been made to patents and printed publications throughout this specification. Each of the above-cited references and printed publications are individually incorporated herein by reference in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

We claim:

1. A method to bond or seal a first piece of glass and a second piece glass of a photovoltaic cell module comprising:
providing said first piece of glass having a planar surface;
providing said second piece of glass having a second planar surface;
providing a photovoltaic cell between said first piece of glass and second piece of glass;
providing an amount of solder to at least one solder contact area disposed on at least one of said first or second pieces of glass;
bringing said first and second pieces of glass into contact at said at least one solder contact area; and
heating said solder to about the melting or working point of said solder;
to provide said first and second pieces of glass with a bond or seal at said at least one solder contact area.

2. The method of claim 1, wherein said solder comprises glass.

3. The method of claim 2, wherein said glass comprises PbO, ZnO, B₂O₃, Bi₂O₃, Ag₂O, Al₂O₃, Li₃O, NaO, or SnO; and combinations thereof.

4. The method of claim 2, wherein said glass comprises PbO, B₂O₃ and ZnO.

5. The method of claim 2, wherein said glass comprises 55% to 65% by weight PbO, 5% to 15% by weight B₂O₃, and 15% to 25% by weight ZnO.

6. The method of claim 1, wherein said solder further comprises at least one thermal expansion coefficient adjusting filler.

7. The method of claim 6, wherein said filler comprises SiO₂, ZrSiO₄, ZnO, or An₃(PO₄)₂; and combinations thereof.

8. The method of claim 1, wherein said solder is free of lead.

9. The method of claim 1, wherein said solder comprises at least one metal.

10. The method of claim 1, wherein said solder comprises glass and at least one metal.

11. The method of claim 1, wherein a polymer encapsulating layer is located between said first piece of glass and said photovoltaic cell.

12. The method of claim 11, wherein said polymer encapsulating layer comprises ethyl vinyl acetate.

13. The method of claim 1, wherein the bottom side of said first piece of glass and the top side of said photovoltaic cell are coated with at least one anti-reflective coating.

14. The method of claim 1, wherein before the solder providing step, a bonding or sealing enhancing layer is applied to said first and/or second pieces of glass.

15. The method of claim 14, wherein said enhancing layer comprises chromium.

16. The method of claim 9, wherein said solder comprises Sn and Bi.

17. The method of claim 1, wherein said heating is local heating.

18. The method of claim 1, wherein said heating is to a temperature of about 200° C. or more.

19. The method of claim 1, wherein said heating is to a temperature of about 300° C. or more.

20. The method of claim 1, wherein said heating is to a temperature of about 700° C. or less.

21. The method of claim 1, wherein said heating is to a temperature of about 500° C. or less.

22. The method of claim 2, wherein said solder glass has a thermal expansion coefficient that is within about 1 ppm of the thermal expansion coefficient of at least one of said first piece of glass and said second piece of glass.

23. The method of claim 2, wherein said solder glass has a thermal expansion coefficient that is within about 0.5 ppm of the thermal expansion coefficient of at least one of said first piece of glass and said second piece of glass.

24. The method of claim 2, wherein said solder glass has a melting temperature of about 700° C. or less.

25. The method of claim 2, wherein said solder glass has a melting temperature of about 500° C. or less.

26. The method of claim 1, wherein said first piece of glass and said second piece of glass are rendered irregular at or near said at least one solder contact area prior to said heating step.

27. The method of claim 2, wherein said solder glass is provided in a medium selected from a solvent, a binder, or combinations thereof.

28. The method of claim 1, wherein said first piece of glass and said second piece of glass respectively comprise a first and second edge and said at least one solder contact area is disposed at or near at least one of said first or second edges.

29. The method of claim 1, wherein said heating step comprises applying heat only at or near said at least one solder contact area.

30. The method of claim 1, wherein said heating step comprises applying heat to at least one of said first or second planar surfaces of said first piece of glass and said second piece of glass only at or near said solder glass contact point.

31. The method of claim 1, wherein said first piece of glass and said second piece of glass are bonded with a distance of about 5, about 4, or about 3 μm between said planar surfaces.

32. The method of claim 1, wherein said first piece of glass and said second piece of glass are bonded with a distance of about 100 μm, or about 200 μm, or about 300 μm to about 600 μm, or about 500 μm, or about 400 μm between said planar surfaces.

33. The method of claim 1, wherein when a polymer encapsulating layer is located between said first piece of glass and said second piece of glass, said heating step comprises applying heat to at least about the melting point or working point of said polymer encapsulating layer and up to about the melting point or working point of said solder glass.

34. The method of claim 1, wherein said heating comprises directed light heating or infrared heating.

35. A photovoltaic cell module comprising:
a first piece of glass;
a second piece of glass;
a photovoltaic cell located between said first and second pieces of glass;
wherein said first piece of glass and said second piece of glass are in contact at one or more solder contact areas; and
further wherein said first and second pieces of glass are bonded or sealed with a solder at said one or more solder contact areas.

36. The photovoltaic cell module of claim 35, wherein said solder comprises glass.

37. The photovoltaic cell module of claim 36, wherein said glass comprises PbO, ZnO, B₂O₃, Bi₂O₃, Ag₂O, Al₂O₃, Li₃O, NaO, or SnO; and combinations thereof.

38. The photovoltaic cell module of claim 36, wherein said glass comprises PbO, B₂O₃ and ZnO.

39. The photovoltaic cell module of claim 36, wherein said glass comprises 55% to 65% by weight PbO, 5% to 15% by weight B₂O₃, and 15% to 25% by weight ZnO.

40. The photovoltaic cell module of claim 35, wherein said solder further comprises at least one thermal expansion coefficient adjusting filler.

41. The photovoltaic cell module of claim 40, wherein said filler comprises SiO₂, ZrSiO₄, ZnO, or An₃(PO₄)₂; and combinations thereof.

42. The photovoltaic cell module of claim 35, wherein said solder is free of lead.

43. The photovoltaic cell module of claim 35, wherein said solder comprises at least one metal.

44. The photovoltaic cell module of claim 35, wherein said solder comprises glass and at least one metal.

45. The photovoltaic cell module of claim 35, wherein a polymer encapsulating layer is located between said first piece of glass and said photovoltaic cell.

46. The photovoltaic cell module of claim 45, wherein said polymer encapsulating layer comprises ethylvinyl acetate.

47. The photovoltaic cell module of claim 35, wherein the bottom side of said first piece of glass and the top side of said photovoltaic cell are coated with at least one anti-reflective coating.

48. The photovoltaic cell module of claim 35, wherein a bonding or sealing enhancing layer is applied to said first and/or second piece of glass.

49. The photovoltaic cell module of claim 48, wherein said enhancing layer comprises chromium.

50. The photovoltaic cell module of claim 45, wherein said solder comprises Sn and Bi.

51. The photovoltaic cell module of claim 35, wherein said solder glass has a thermal expansion coefficient that is within about 0.5 ppm of the thermal expansion coefficient of at least one of said first piece of glass and said second piece of glass.

52. The photovoltaic cell module of claim 35, wherein said solder glass has a thermal expansion coefficient that is within about 0.5 ppm of the thermal expansion coefficient of at least one of said first piece of glass and said second piece of glass.

53. The photovoltaic cell module of claim 35, wherein said solder glass has a melting temperature of about 700° C. or less.

54. The photovoltaic cell module of claim 35, wherein said solder glass has a melting temperature of about 500° C. or less.

55. The photovoltaic cell module of claim 35, wherein said first piece of glass and said second piece of glass are rendered irregular at or near said one or more contact areas prior to heating.

56. The photovoltaic cell module of claim 35, wherein said first piece of glass and said second piece of glass respectively comprise a first and second edge and said one or more contact areas is disposed at or near at least one of said first or second edges.
